(19) United States
(12) Patent Application Publication
(10) Pub. No.: US 2009/0167394 A1
(43) Pub. Date: Jul. 2, 2009

(54) INTEGRATED CIRCUITS HAVING DEVICES IN ADJACENT STANDARD CELLS COUPLED BY THE GATE ELECTRODE LAYER

(75) Inventor: Patrick Bosshart, Plano, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/967,943

(22) Filed: Dec. 31, 2007

(51) Int. Cl. H03K 3/3562; G06F 17/50

(52) U.S. Cl. 327/203; 716/8

(57) ABSTRACT

An integrated circuit (500) includes an array of standard cells including at least a first and a second standard cell (501-504). At least one device in the first standard cell is directly coupled to at least one device in the second standard cell by a gate electrode layer (515) of the integrated circuit. The array of standard cells can implement flip-flops which significantly decrease the switching capacitance.

### TECHNICAL FIELD OF THE INVENTION

This invention relates generally to digital logic comprising integrated circuits formed from standard cells that receive one or more complementary input signals.

### BACKGROUND

Registers, also called flip-flops or simply flops, are very common elements in digital logic design of integrated circuits. It is not uncommon for them to consume 40% of the gate count in a large digital chip. They are also important consumers of power on-chip. This is due not only to their large number of instances in typical designs, but also due to the high transition frequency on their clock input pin. Whereas typical static signals transition at most once per clock cycle, and often do not transition at all, the flop's clock signal transitions up and down for a total of twice per clock cycle.

The power dissipated by the flop during cycles where the clock transitions but the input data (e.g. the D input in the case of a D flop) does not transition is called the non-toggling power of the flop. This is basically the energy required in each cycle to charge and discharge all the capacitances on the clock nodes of the flop. The amount of clock capacitance can be understood by reference to FIG. 1, which shows the schematic of a typical scan flop 100. Scan flop 100 is shown in three serially connected sections, a scan multiplexer (mux) 110, a master latch 120, and a slave latch 130. Scan flop 100 includes two inverters 131 and 132 which provide complementary versions of the clock (elk) and scan enable (se) signals, respectively. Both clk and the clock complement or inverted clock (clkx) connect to both latches 120 and 130. There are a total of 8 load transistors connected to clk and clkx.

In the layout of the flop cell 100, the wiring to make the required connections results in significant capacitance on both the elk and clkx lines. The power to drive the elk node is dissipated externally by the gate driving the elk signals, while the power to drive clkx, is dissipated by the elk inverter 131 inside the flop cell 100.

As known in the art, standard cells are the most common application specific integrated circuit (ASIC) development technology. Each standard cell vendor has its own library of circuits that range from primitive logic gates to more complex functions such as memory blocks and microprocessor cores. Based on the customer's design, the required circuits are placed on the chip and connected by one or more metal interconnect levels using “place-and-route” software.

FIG. 2 shows a conventional standard cell-based layout arrangement 170 for the flop cell 100 shown in FIG. 1. For simplicity, only the gate electrode layer defining the gates (shown darkened), the p-diffusions (shown as P) and n-diffusions (shown as N), and a single metal strap coupling the p-diffusion to the n-diffusion associated with clkx, are shown. It can be seen that both elk and clkx connect to many places, making some relatively long lengths of wire unavoidable. In addition, the cell layout 170 has a border region 115 on the top and bottom of the cell, which generally comprises field oxide or other isolation region. The respective diffusions and the gate electrode layer are not included inside the border region 115. As known in the art, in standard cell designs each cell is considered as a separate entity, and may only be legally placed up against another other cell if no width, spacing or other design rule violations occur. Generally, this approach results in an empty border region 115 that is void of geometries (e.g. diffusions or poly) around the periphery of the cell 100, thus requiring interconnection between adjacent cells using one or more metal interconnect layers of the integrated circuit, such as metal1 or metal2.

As known in the art, reducing the total capacitance on clk and clkx reduces the non-toggling power of the flop, which is the dominant portion of its power dissipation. Reducing the total capacitance on clk and clkx generally requires decreasing the sizes of the transistors coupled to the elk and clkx nodes or reducing the length of the wiring, or both.

Since flops are generally important elements of any standard cell library, it is customary that significant efforts are expended when doing the layout of flop cells, so that power (and area) are minimized by the layout. Since the flop 100 shown in FIG. 1 or something very similar (e.g. a flop using some form of complementary pass gate) has been the flop arrangement generally used for about the past 15-20 years and since essentially every company in the semiconductor business uses these flops and many design them, despite being highly desirable, further improvements towards capacitance reduction would be expected to be small and difficult to achieve.

### SUMMARY

This Summary is provided to comply with 37 C.F.R. §1.73, requiring a summary of the invention briefly indicating the nature and substance of the invention. It is submitted with the understanding that it will not be used to interpret or limit the scope or meaning of the claims.

An integrated circuit includes an array of standard cells including at least a first and a second standard cell. At least one device in the first standard cell is directly coupled to at least one device in the second standard cell by a gate electrode layer of the integrated circuit. As defined herein, “directly coupled” refers to a low resistance connection without any intervening devices, such as diodes or transistors. In one embodiment, a flip flop is described which significantly decreases the switching capacitance on the CLK and inverted clock/clock complement (hereafter CLKX) nodes of the flop, thereby decreasing power dissipation for integrated circuit.

### BRIEF DESCRIPTION OF THE DRAWINGS

FIG. 1 is the schematic of a conventional scan flop circuit.

FIG. 2 is a conventional standard cell layout for the scan flop shown in FIG. 1.

FIG. 3 is an exemplary layout for a three (3) bit register using scan flop cells according to an embodiment of the present invention.

FIG. 4A is an exemplary arrangement according to an embodiment of the invention for the slave latch sections of four (4) stacked mirrored flop cells, according to an embodiment of the invention.

FIG. 4B is another exemplary arrangement for the slave latch sections of a stack of four (4) flop cells according to an embodiment of the present invention.

FIG. 5 is an exemplary arrangement for a four (4) bit register comprising a stack of flop cells according to another embodiment of the present invention.

FIG. 6 is an exemplary layout of a portion the gate electrode layer for the latch portions of the stack shown in FIG. 5.

FIG. 7 depicts an exemplary schematic of interconnections within the master and slave latch portions of a flop cell, according to an embodiment of the present invention.

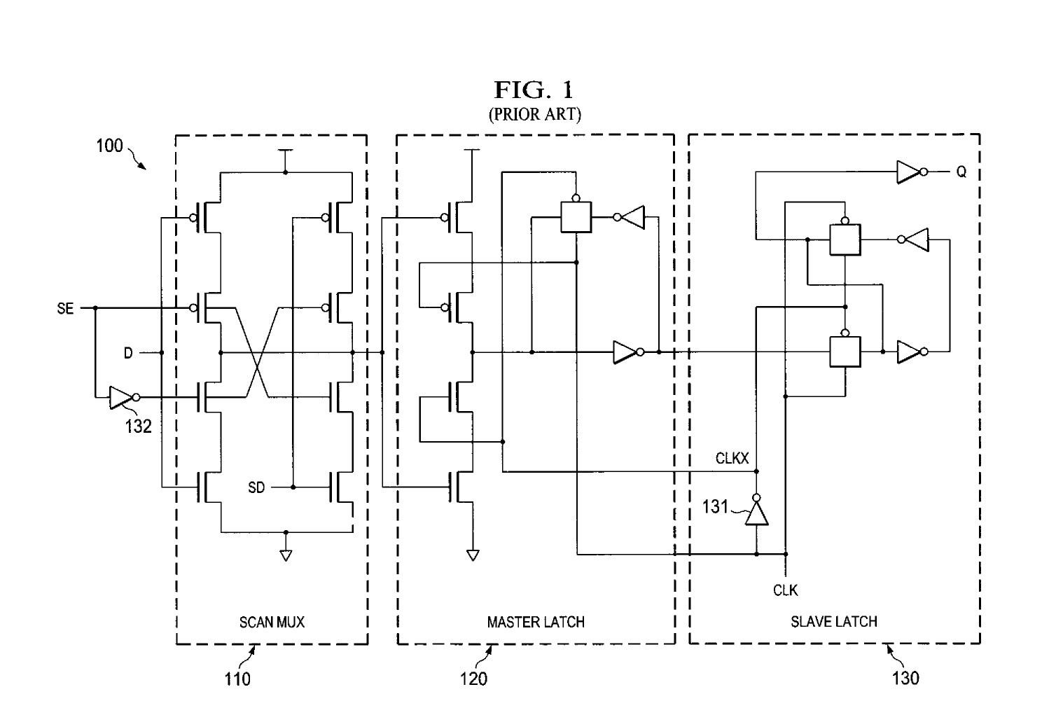

### DETAILED DESCRIPTION OF THE DRAWINGS

The present invention is described with reference to the attached figures, wherein like reference numerals are used throughout the figures to designate similar or equivalent elements. The figures are not drawn to scale and they are provided merely to illustrate the instant invention. Several aspects of the invention are described below with reference to example applications for illustration. It should be understood that numerous specific details, relationships, and methods are set forth to provide a full understanding of the invention. One having ordinary skill in the relevant art, however, can recognize that the invention can be practiced without one or more of the specific details or with other methods. In other instances, well-known structures or operations are not shown in detail to avoid obscuring the invention. The present invention is not limited by the illustrated ordering of acts or events, as some acts can occur in different orders and/or concurrently with other acts or events. Furthermore, not all illustrated acts or events are required to implement a methodology in accordance with the present invention.

An integrated circuit according to an embodiment of the invention comprises an array of standard cells including at least a first and a second standard cell. At least one device in the first standard cell is directly coupled to at least one device in the second standard cell by a gate electrode layer of the integrated circuit. The gate electrode layer can comprise polysilicon (sometimes referred to herein as poly), other silicon comprising interconnect (e.g. silicide), silicided poly, or a metal (e.g. in a replacement gate or metal gate process). As known in the art, standard cells typically have a constant size in at least one dimension, and a border region devoid of devices or layers other than metal interconnect layers that allows them to be lined up in rows on the integrated circuit. As defined herein, “directly coupled” refers to a low resistance connection without any intervening devices, such as diodes or transistors, or via connections, such as in the cases of metal connections.

The invention is a significant departure from conventional standard cell designs cell because the separate cell entity and metal interconnect only cell to cell connections used by conventional standard cell designs is generally ignored. As described above, conventional standard cell-based integrated circuits utilize a plurality of standard cells, where each cell is considered as a separate entity, and may only be legally placed up against another other cell if no width, spacing or other design rule violations occur. Although expediting the design process, this approach results in an empty border around the periphery of the cell, requiring interconnection between adjacent cells using one or more metal interconnect layers of the integrated circuit. Embodiments of the present invention generally ignore this conventional requirement by including some portion of the gate electrode layer which runs to the top and bottom edge of the cell. As described below, embodiments according to the invention can increase circuit density as well as decrease capacitance (and thus provide a significant reduction in non-toggling clock power in the case of flip-flop comprising circuits) as compared to conventional standard cell designs.

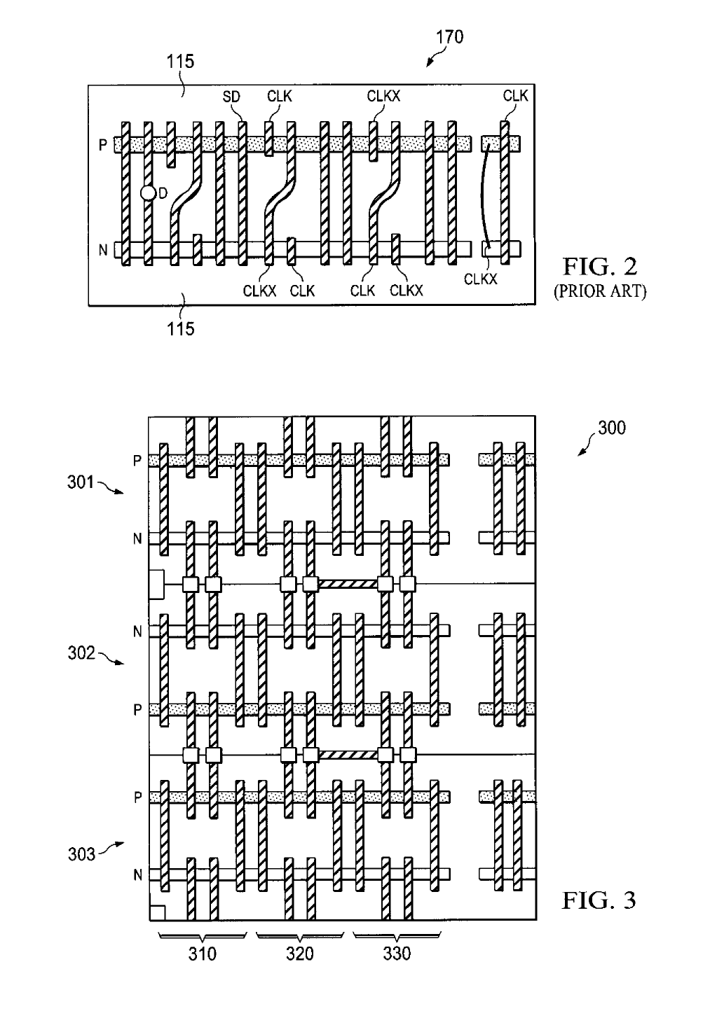

In the case of a flop cell according to an embodiment of the invention, the flop cell is adapted to be laid out in a vertically stacked array of such cells. A register 300 comprising three (3) stacked flop cells (bits) 301, 302 and 303 of exemplary layout arrangement according to the invention is shown in FIG. 3. Although not shown in this and subsequent FIGs., whitespace is present on the left and right side of the respective standard cells analogous to border region 115 shown in FIG. 2. Adjacent rows are shown mirrored upside down relative to one another. The layout of each cell 301-303 is similar to the conventional standard cell layout shown in FIG. 2, except now, looking at the middle cell 302, by extending the gate electrode layer to the top and bottom of the cell, the mirroring and stacking of the cells exposes 6 available connections on each of the top and bottom edges of the cells. The shared connections are shown outlined in FIG. 3, only to highlight their presence. There are two shared connections in the scan mux portion 310 of the cell, sharing both polarities of the SCAN enable signal with the neighbors 301 and 303 above and below cell 302. In the master latch section 320 of each cell, there are two shared connections between cell 302 and each of the cells 301 and 303, sharing the CLK and CLKX signals. In the slave latch section 330 of cell 302 there are also two shared connections with each of the neighbors 301 and 303, again sharing CLK and CLKX. All of these connections are shown made by violating conventional design rules by continuing the gate electrode geometries vertically to the top or bottom edges of the flop cell.

In FIG. 3 there is also shown two horizontally oriented gate electrode (e.g. poly) connections, one along the top edge of the cell 302 and the other along the bottom edge of cell 302. These connect a CLK or CLKX node in the master latch section 320 to the analogous node in the slave latch section 330. In comparison, the convention standard cell flop layout shown in FIG. 2 has only one or at most two transistors coupled per poly geometry, while the flop cell according to an embodiment of the invention shown in FIG. 3 provides at least 2 and 4 transistors in some cases on each gate electrode (e.g. poly) line, thus significantly reducing the number of connections required to be made in interconnect metal. The gate electrode interconnect between cells proximate to the border region is generally over isolation regions, such as comprising a thick oxide region, for example field oxide.

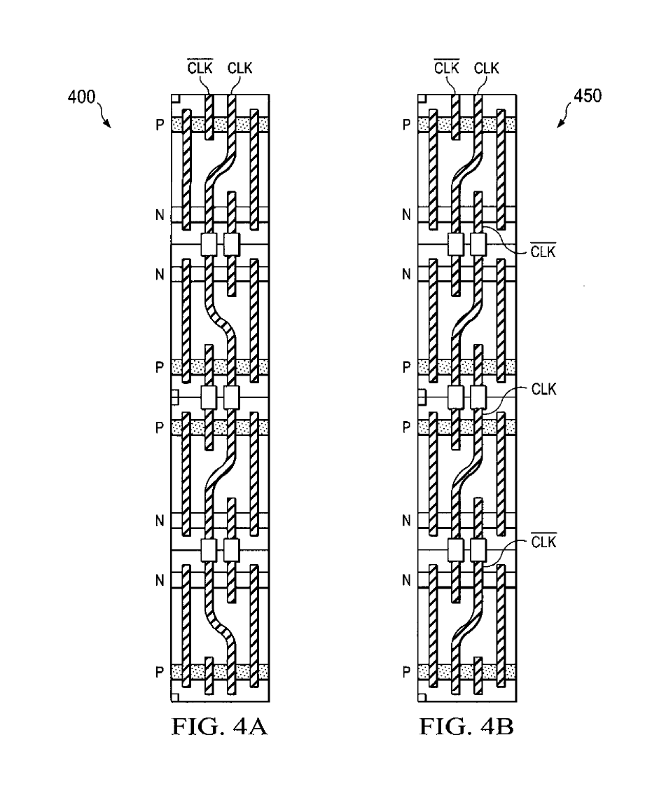

Note that in FIG. 2 there are connections shown where the poly jogs horizontally between the P and N diffusion sections in order to make a connection. Herein, these will be called pass gate crossover connections or jog (or jogged) connections. Such crossovers have been excluded in FIG. 3 and are provided in an arrangement different as compared to cell layout 170 shown in FIG. 2, such as in FIGS. 4A and B described below.

FIG. 4A shows an exemplary layout according to an embodiment of the invention 400 for the slave latch section of a stack of four (4) flops showing gate electrode (e.g. poly) jogs. Due to stacking and flipping of the cells, one of the nodes, CLK, is seen to be connected all the way through the stack, whereas the other node, CLKX, receives no additional connections. CLK being connected in a gate electrode material such as poly completely through the stack is generally of little use, since such a long connection, particularly in the case of poly, would suffer too much RC delay to generally be useful, and would generally still require metal connections at frequent intervals.

FIG. 4B shows another exemplary layout according to an embodiment of the invention 450 for the slave latch section of a flop stack which provides an improved arrangement for the crossover connections. Whereas in the layout shown in FIG. 4A the crossovers were a part of the primitive cell and so were mirrored with it every other bit, in FIG. 4B the crossovers are not mirrored, but are in the same orientation each cell (so therefore cannot be a part of the primitive one bit cell). Every gate electrode (e.g. poly) crossover comprising geometry thus connects to four (4) transistors, and all the gate electrode geometries are the same length, short enough that a single connection from metal is sufficient. This layout results in a reduced number of required connections from metal as compared to the other layout arrangement shown in FIG. 4A.

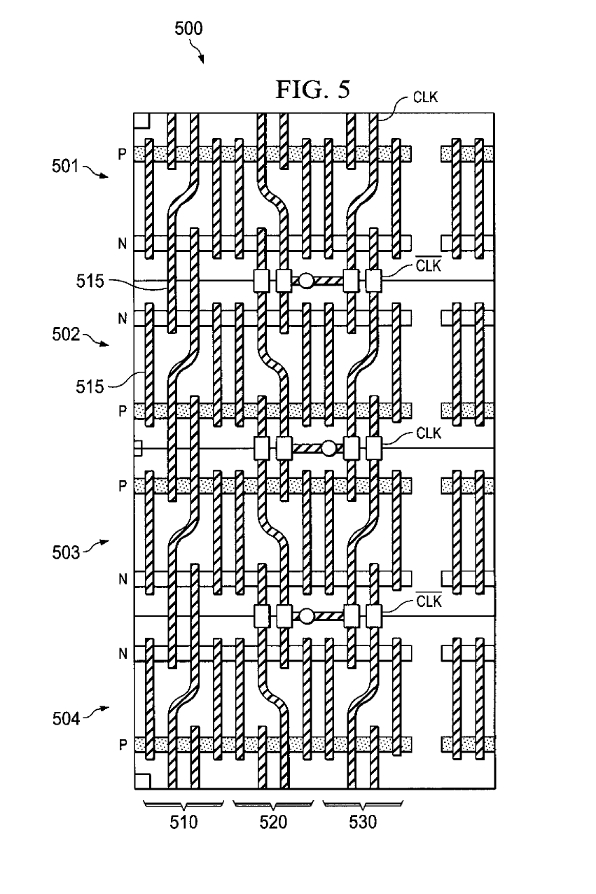

FIG. 5 is an exemplary layout arrangement 500 for a four (4) bit register comprising a stack of standard cell-based flop cells 501-504 according to another embodiment of the present invention which combines features shown in FIG. 3 and FIG. 4B. At least one device in each standard cell (501-504) is directly coupled to at least one device in another of the standard cells (501-504) by a gate electrode layer 515 of the integrated circuit. Layout 500 provides shared vertically oriented connections across the top and bottom edges of the cells, with the horizontal gate electrode 515 (e.g. poly) connections at the top and bottom edges, and with the gate electrode (e.g. poly) jog arrangement shown in FIG. 4B. Each cell includes scan multiplexer (mux) 510, master latch 520 and slave latch 530. Although shown including scan mux 510, as known in the art useful circuits, such as non-scanned flops, can be formed without scan mux 510. The gate electrode layer 515 (e.g. poly, generally silicided poly) crossover connections in the master latch 520 and slave latch 530 are shown in opposite directions. The result is that one gate electrode (e.g. poly) geometry connects to 8 transistors, requiring only one connection to interconnect metal to connect to the 8 interconnected transistors. In FIG. 5, the circles shown indicate the locations of connections straddling the top/bottom edges of the cell from the gate electrode layer 515 (e.g. poly) to a metal such as metal1. In the stack, there is only one connection to metal required per bit for CLK and CLKX since CLK can be connected on every other bit, and CLKX connected on the alternate bits.

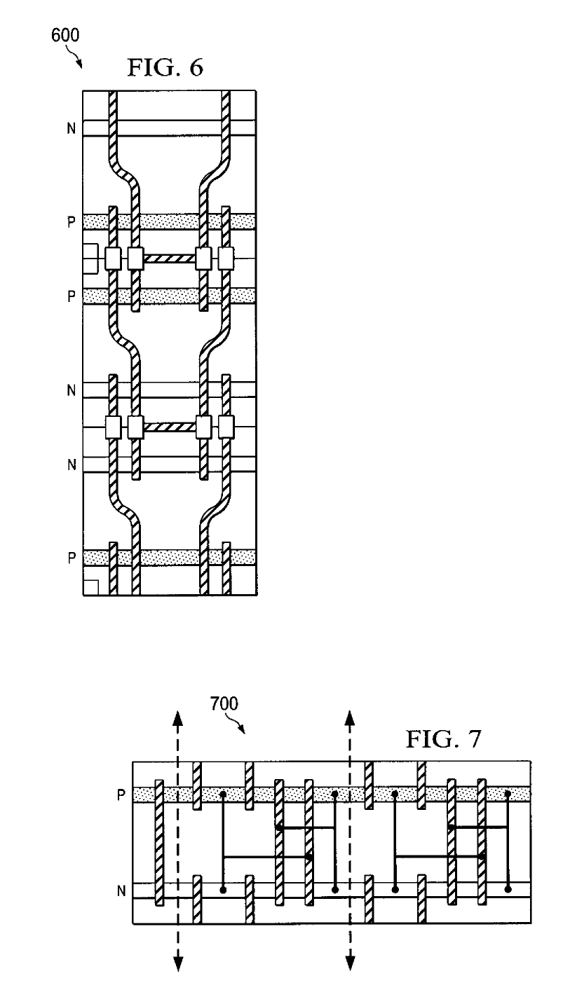

FIG. 6 is a layout schematic 600 showing the gate electrode layer (e.g. poly) topology repeated for each bit to achieve the 8 transistors connected gate electrode (e.g. poly) geometry. Each gate electrode geometry is seen to span to contact devices across 3 bits.

FIG. 7 shows a flop cell 700 having additional detail in the master and slave latch sections, according to an embodiment of the invention. The black lines show the metal connections from transistor outputs to transistor gates. The two dotted vertical lines indicate available (free) space which can be used to route a metal interconnect layer, such as metal1, in the direction shown. These two tracks can be used to route CLK and CLKX vertically as shown through the stack of bits, where one will make a connection to the gate electrode layer (e.g. poly) for each bit as indicated in FIG. 5. In this way some of the clock routing is included inside the cell. Furthermore, the small clock inverter to generate CLKX in each cell is eliminated, eliminating its parasitic capacitance. One large inverter driving the whole stack can be used instead of many smaller ones.

The bits at the top and bottom of the stack are generally slightly different. For example, the gate electrode (e.g. poly) geometries for the top and bottom cells do not go to the outside top or bottom edge of the cell, and there are two isolated transistors which have to be connected in metal to each other and the vertically broadcast CLK or CLKX wire. The inner bit cells also differ from conventional standard cells in that the poly crossover connections are different for even and odd bits as shown in FIG. 4B. This can be accomplished in one of two ways. Either separate layout versions can be made for even and odd bits, or an overlay cell can be created to include the poly crossovers. The overlay cell would use separate even and odd bit versions.

The arrangements for both polarities of the other complementary signal, the scan enable signal, can be similar to the CLK or CLKX described above. The gate electrode layer crossover can go in the same direction every bit, connections can be shared across the cell top and bottom borders, and both polarities of the SCAN enable signal and the complement of SCAN enable signal (SCANX) can be broadcast vertically in metal up the bitstack.

Typically, according to embodiments of the invention, the cell layout can use the space all the way to the top and bottom edges of the cell. So even though in the top and bottom edge cells the poly can be retracted, there can remain less than legal design rule spacings to an adjacent vertical cell. So typically the area above and below the flop cannot be used by typical library cells.

The CLK signal can be buffered, and inverted to provide CLKX, so that only a single clock input to the stack is generally required for CLK and CLKX. The same approach can be used for the SCAN buffer and inverters. These inverters can be located at the bottom of the stack. The CLK and SCAN buffers might use the cell below the flop bitstack, but the one row space above it would generally be unusable. Alternately, the top and bottom edge bit layouts could be altered to leave legal spacings on the outside top/bottom edge so that any standard cell could be placed above the stack. In that case, the CLK and SCAN inverters could also be in the middle of the stack without losing the placeable locations above and below the stack. In another embodiment of the invention, the CLK and SCAN buffers can be at the top of the stack.

Although a flip-flop comprising integrated circuit has generally been discussed in accordance with the present invention, the present invention is applicable to a variety of other circuits, such as any circuit operable to process one or more broadcasted complementary signals. Moreover, the invention is also not limited to the use of silicon wafers, and may be implemented in association with the manufacture of various semiconductor devices.

Although the invention has been illustrated and described with respect to one or more implementations, equivalent alterations and modifications will occur to others skilled in the art upon the reading and understanding of this specification and the annexed drawings. In particular regard to the various functions performed by the above described components (assemblies, devices, circuits, systems, etc.), the terms (including a reference to a “means”) used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and/or the claims, such terms are intended to be inclusive in a manner similar to the term “comprising.”

The Abstract of the Disclosure is provided to comply with 37 C.F.R. §1.72(b), requiring an abstract that will allow the reader to quickly ascertain the nature of the technical disclosure. It is submitted with the understanding that it will not be used to interpret or limit the scope or meaning of the following claims.

What is claimed is:

1. An integrated circuit, comprising:
an array of standard cells comprising at least a first and a second standard cell, wherein at least one device in said first standard cell is directly coupled to at least one device in said second standard cell by a gate electrode layer of said integrated circuit.

2. The integrated circuit of claim 1, wherein said first and second cells share a common border, wherein said direct connection is over said common border.

3. The integrated circuit of claim 2, wherein at least one intra-cell connection between devices within said first and said second cell is provided by said gate electrode layer over said common border.

4. The integrated circuit of claim 1, wherein said first and second standard cells comprise flip-flops.

5. The integrated circuit of claim 1, wherein said first and second standard cells are arranged in a stacked array.

6. The integrated circuit of claim 5, wherein exclusive of said gate electrode layer at least some of said cells in said stacked array are mirror images of adjacent ones of said cells in said stacked array.

7. The integrated circuit of claim 1, wherein said first and second cells each include at least one pair of signal nodes, wherein a first node of said pair of signal nodes is operative to receive a common signal for said first and second cells and a second node of said pair of signal nodes is operative to receive a complement of said common signal.

8. The integrated circuit of claim 7, wherein said common signal comprises a clock signal, said first and said second node for said first and second cells being provided in said gate electrode layer and positioned across a top and a bottom edge of said first and second cell.

9. The integrated circuit of claim 7, wherein said array comprises a first cell type having a first cell layout, said first layout including said first node comprising a first jogged connector formed from said gate electrode layer that jogs and extends a full height of said first cell type and a second cell type having a second layout different from said first layout having said second node which includes a second jogged connector formed from said gate electrode layer that jogs and extends a full height of said second cell type, said array alternating said first and second cell types.

10. The integrated circuit of claim 9, wherein said first jogged connector and said second jogged connector are both v-shaped.

11. The integrated circuit of claim 8, wherein said cells comprise, serially coupled, a master latch and a slave latch, each of said first and second nodes directly connecting said master latch to said slave latch in said cells by a horizontally oriented segment of said gate electrode layer.

12. The integrated circuit of claim 11, further comprising a scan multiplexer serially coupled to said master latch and said slave latch.

13. The integrated circuit of claim 5, wherein connections to both said first and second node are routed along a height of said stacked array in a metal comprising layer and make a single connection to only one of said first and said second node for each of said cells.

14. The integrated circuit of claim 13, wherein said single connection alternates between said first and said second node.

15. The integrated circuit of claim 14, wherein said metal comprising layer comprises first or second level metal.

16. A method of designing a standard cell-based integrated circuit, comprising:
placing a plurality of circuit elements, wherein said circuit elements comprise a plurality of standard cells including a first and second standard cell, said first and second cells including at least one device having a gate electrode layer extending to an edge of said cell, and
stacking said first and second standard cell, wherein said stacking directly connects said device in said first cell to said device in said second cell by said gate electrode layer of said integrated circuit.

17. The method of claim 16, wherein said first and second cells share a common border, wherein said direct connection is over said common border.

18. The method of claim 16, wherein said first and second cells each include at least one pair of signal nodes, wherein a first node of said pair of signal nodes is operative to receive a common signal for said first and second cells and a second node of said pair of signal nodes is operative to receive a complement of said common signal.

19. The method of claim 18, further comprising the step of generating a first cell layout implementing a first cell type and a second cell layout implementing a second cell type, wherein said first layout includes said first node comprising a first jogged connector formed from said gate electrode layer that jogs and extends a full height of said first cell type and a second cell type having a second layout different from said first layout having said second node which includes a second jogged connector formed from said gate electrode layer that jogs and extends a full height of said second cell type, said array alternating said first and second cell types.

20. The method of claim 19, wherein said first jogged connector and said second jogged connector are both v-shaped.

21. An integrated circuit, comprising:
a stacked array of standard cells comprising at least a first and a second flip flop, wherein at least one device in said first flip flop is directly coupled to at least one device in said second flip flop by a gate electrode layer of said integrated circuit, said first and second flip flops sharing a common border, wherein said direct connection is over said common border,
wherein said first and second cells each include at least one pair of signal nodes, wherein a first node of said pair of signal nodes is operative to receive a clock signal for said first and second flip flops and a second node of said pair of signal nodes is operative to receive a complement of said clock signal.

22. The integrated circuit of claim 21, wherein connections to both said first and second node are routed along a height of said stacked array in a metal comprising layer and make a single connection to only one of said first and said second node for each of said first and second flip flops.

23. The integrated circuit of claim 21, wherein said first flip flop comprises a first cell type having a first cell layout, said first layout including said first node comprising a first jogged connector formed from said gate electrode layer that jogs and extends a full height of said first cell type and said second flip flop comprises a second cell type having a second layout different from said first layout having said second node which includes a second jogged connector formed from said gate electrode layer that jogs and extends a full height of said second cell type, said array alternating said first and second cell types.

24. The integrated circuit of claim 23, wherein said first jogged connector and said second jogged connector are both v-shaped.
